(19) United States
(12) Patent Application Publication
(10) Pub. No.: US 2010/0065895 A1
(43) Pub. Date: Mar. 18, 2010

(54) Method for producing at least one porous layer

(76) Inventors: Richard Fix, Gerlingen (DE); Oliver Wolst, Nuertingen (DE); Markus Widenmeyer, Schoenaich (DE); Alexander Martin, Ludwigsburg (DE)

Correspondence Address: KENYON & KENYON LLP, ONE BROADWAY, NEW YORK, NY, 10004, US

(21) Appl. No.: 12/311,707

(22) PCT Filed: Oct. 10, 2007
(86) PCT No.: PCT/EP2007/060760

§ 371 Date: Dec. 3, 2009

(30) Foreign Application Priority Data
Oct. 10, 2006 (DE) 10 2006 047 928.9

(51) Int. Cl. H01L 29/66; H01L 21/44; H01L 21/469

(52) U.S. Cl. 257/288; 438/660; 438/765; 257/E29.166; 257/E21.476; 257/E21.487

(57) ABSTRACT

A method for producing at least one porous layer on a substrate, whereby a suspension, which contains particles from a layer-forming material or molecular precursors of the layer-forming material, as well as at least one organic component, is applied to the substrate, the precursors of the layer-forming material are subsequently reacted to produce the layer-forming material following application to the substrate, in a next step, the particles from the layer-forming material are sintered, and the at least one organic component is subsequently removed. Also, a field-effect transistor having at least one gate electrode, the gate electrode having an electrically conductive, porous coating which was applied in accordance with the method.

### FIELD OF THE INVENTION

The present invention relates to a method for producing at least one porous layer on a substrate.

### BACKGROUND INFORMATION

Porous layers of this kind are used, for example, for gate electrodes of field-effect transistors, which function as gas sensors.

Gate electrodes of semiconductor transistors are presently manufactured in the course of transistor processing by the sputter- or vapor-deposition of metals, such as aluminum, platinum, nickel, etc. The gate layers, which are deposited at room temperature, are virtually closed, non-porous and thermally unstable metallic films, which, at higher temperatures, i.e., at temperatures of more than 200° C., lose their macroscopic structure. As a consequence, the electrochemical properties of the gate electrodes change, and the sensor properties are thus unstable over the operational life, or the sensor function of the field-effect transistor even completely fails. Also, because the gate electrode structures are not well defined when working with sputter- or vapor-deposited gate layers, highly sensitive or selective processes involving substances, i.e., a selective adsorption of gases and/or catalytic reactions, are not readily possible. The porosity of the sputter- or vapor-deposited gate layers cannot be selectively adjusted.

### SUMMARY OF THE INVENTION

The method according to the present invention for producing at least one porous layer on a substrate includes the following steps:
(a) applying a suspension, which contains particles from a layer-forming material or molecular precursors of the layer-forming material, as well as at least one organic component, to the substrate;
(b) optionally reacting the precursors of the layer-forming material to produce the layer-forming material following application to the substrate;
(c) annealing the particles from the layer-forming material;
(d) removing the at least one organic component.

Steps (a) through (d) may be repeated to produce thicker porous layers. Steps (a) through (c) may be repeated until an adequate layer thickness is attained; step (d) is subsequently carried out.

The advantage of the method according to the present invention is that, by using the organic component, which is contained in the suspension, and subsequently removing the same, a uniform porous structure is achieved. The organic component prevents particles from the layer-forming material from agglomerating, which would restrict or prevent the formation of the desired layer.

The layer-forming component is a metal, a ceramic, or a mixture of metal and ceramic, what is generally referred to as a cermet. It is also possible that the layer-forming component contain a mixture of a plurality of metals, a plurality of ceramics, or a mixture of metal and ceramic. Suitable metals are elements of the 8th, 9th, 10th or 11th group of the periodic system, for example. Especially suited metals are platinum, palladium, gold and iridium. Ceramics may be, for example, aluminum oxide, silicon oxide, zirconium oxide or magnesium oxide.

When the porous layers produced in accordance with the present invention are used for gate electrodes of field-effect transistors, for example, the porous layer must be electrically conductive. If ceramics that are not electrically conductive are contained in the porous layer, then an electrically conductive material, which may be a metal, must be additionally contained. For an electrically conductive layer, the ratio of electrically conductive material to non-conductive ceramic applies:

$$\frac{M}{K} = 1.2 \cdot ( \frac{{V}_{M}}{{V}_{K}} ) \cdot ( \frac{{D}_{K}}{{D}_{M}} ) \qquad ( I )$$

In equation (I), V_{M} signifies the volume fraction of the metal, V_{K} the volume fraction of the ceramic, D_{K} the average diameter of the ceramic particles, D_{M} the average diameter of the electrically conductive particles.

The organic component, which is contained in the suspension, which may include monomers, oligomers or polymers, which can cure to form a polymer matrix, at least one solvent, or a mixture thereof.

Suitable polymers are, for example, polyethylene glycol and derivatives thereof or polyethylene imine. Suitable monomers or oligomers are, for example, lactams, vinyl derivatives or styrene derivatives. When the monomers or oligomers are present in liquid form, they may be optionally used as solvents, and the need for another organic solvent may be eliminated. The organic solvent is generally applied to adjust the viscosity of the suspension. Suited as solvents are, for example, alcohols, ether, glycol derivatives, N-containing solvents.

In one specific embodiment, the suspension also contains organic particles as a structure-directing component. The organic particles, which act as a structure-directing component, are likewise removed in step (d). Thus, the organic particles acting as a structure-directing component likewise influence the porosity of the porous layer. The organic particles may be provided in a size within the range of 10 to 1000 nm. Suitable organic particles are, for example, pyrolytic carbon black, latex spherules, macromolecules or surfactants.

To ensure that the particles of the layer-forming material remain homogeneously distributed in the suspension, one specific embodiment provides that at least one stabilizing agent be added to the suspension. Suited as stabilizing agents are, for example, oxygen-, nitrogen- or phosphorus-containing, organic, mostly gelatinizing complexing agents, for example, derivatives of polyethylene oxides, of phenanthrolines or multivalent alcohols. A suitable stabilizing agent is, for example, diethylene glycol monobutylene ether. Alternatively, the organic substances mentioned above may also be used as stabilizing agents.

Once the suspension is applied, it may be that the solvent contained in the suspension be at least partially removed first by drying. Removing the solvent forms a regular arrangement of the particles of the layer-forming material. The monomers or oligomers, which may cure to form the polymer matrix, are located in the interstices between the particles, for example.

Once the suspension is applied and drying has been optionally carried out, during which solvent contained in the suspension is removed, monomers or oligomers contained in the suspension are optionally cured to form a polymer matrix. In this context, the polymer matrix is located in the interstices between the particles of the layer-forming material. This prevents the particles of the layer-forming material from being able to agglomerate. Initially, the particles of the layer-forming material are regularly distributed in the cured polymer matrix.

Once the monomers or oligomers have cured to form the polymer matrix, the ceramic or metallic particles or the mixture of ceramic and metallic particles are/is sintered. The polymer, which is located in the interstices between the particles of the layer-forming material, is removed during or subsequently to the sintering. As a result, a porous layer is formed. The organic polymer matrix is removed by burning out of the same, for example. Alternatively, however, the polymer matrix may also be dissolved from the layer using suitable solvents. Subsequently thereto, it is necessary, however, to remove the solvent.

The layer-forming particles contained in the suspension which may have an average diameter within the range of 0.5 to 1000 nm. The average diameter of the layer-forming particles may be within the range of 0.5 to 100 nm, and, in particular, within the range of 1 to 20 nm.

In one specific embodiment, the layer-forming particles are present in a colloid. At least one element of the 8th, 9th, 10th or 11th group of the periodic system, in particular platinum, palladium, gold, silver, rhodium and iridium, is used as material for the layer-forming particles. To produce the metal colloids, the at least one metal, for example in the form of its salt or in the form of an organometallic compound, is dissolved in a solvent and reduced under agitation. In this context, suitable salts are nitrates, chlorides, bromides or carbonates. Suitable organometallic compounds are acetates, alcoholates, acetylacetonates or corresponding organometals in a suitable solvent, such as an alcohol, ether, glycol derivative or N-containing solvents. The dissolved metallic salts or organometallic compounds are subsequently subjected to various reduction conditions. Formaldehyde, formic acid, ethanol, a mixture of formic acid and ethanol, a mixture of citric acid and ethanol, a mixture of ascorbic acid and ethanol, hydrazine, hydrogen, borane derivatives or a mixture of glyoxylic acid and ethanol are used as reducing agent, for example, for producing platinum colloids. The appropriate reducing agents are applied in each case in excess relative to the platinum. The dissolved metal salts are reduced under agitation. The reducing process takes place within a time period from five minutes up to several days. The metal particle sizes in the colloid that are attained in this case are within the range of between 0.5 to 100 nm, which may be within the range of between 1 to 20 nm. The metal concentrations are within the range of 0.01 to 15% by weight, which may be within the range of 0.5 to 5% by weight.

Alternatively, it is also possible to produce the metal particles on the support material, for example a gate of a semiconductor transistor. To this end, the corresponding oxometal colloids on the support material are reduced. The reduction may be carried out, for example, using gaseous hydrogen or organic layer components.

The suspension, which contains the particles from the layer-forming material or molecular precursors of the layer-forming material, is applied to the substrate, for example, by dripping using a microsyringe, by spincoating in the case of a higher-viscosity suspension or, for example, using a thick-layer printing technique when the suspension is provided as a paste.

The thickness and the porosity of the porous layer are adjusted by varying the concentration of the suspension, the thickness of the application of the suspension, or possibly also by using a multiple coating. A multiple coating is particularly advantageous when layer-forming material is to be applied in quantities greater than that contained by the suspension for a given drop volume. A multiple coating connotes a repeated application and drying of the particles of layer-forming material or of the suspension containing molecular precursors of the layer-forming material. Alternatively, a thermolysis or a burning-out process may also be carried out following the application of the suspension and prior to the application of the next layer. An application in a plurality of layers is necessary, for example, when it is only possible to adjust a small concentration of layer-forming material in the suspension due to an agglomeration of the particles of the layer-forming material.

The application of the suspension may be followed by a thermal treatment. This includes a preliminary drying, thermolysis or pyrolysis and thermal sintering of the particles from the layer-forming material. The preliminary drying may take place at a temperature within the range of 20 to 150° C. As a result of the preliminary drying, solvent is removed from the suspension. This effects a freezing of the solution, i.e., what is generally referred to as lacquer formation, which prevents an undesirable agglomeration of the particles from the layer-forming material. A uniform distribution of the particles from the layer-forming material is hereby realized in the form of a porous film on the substrate. The preliminary drying is followed by a thermolysis or pyrolysis step at a temperature within the range of 100 to 650° C. The organic components of the suspension are completely removed by the thermolysis or pyrolysis. Merely the inorganic components remain. The maximum temperature may be reached in one step or also in a plurality of half steps with residence times occurring therebetween.

It is also possible for different atmospheres to be used during the thermolysis or the pyrolysis. Thus, for example, the thermolysis or pyrolysis may be carried out in the presence of air, in the presence of an inert atmosphere, for example in the form of pure nitrogen, or in the presence of a reducing atmosphere, for example in the presence of a mixture of nitrogen and hydrogen, the hydrogen concentration in the mixture amounting to 0.5 to 10% by volume.

The porous layer produced using the method according to the present invention may be used for semiconductor transistors having at least one gate electrode which has an electrically conductive porous coating. Transistors of this kind are used as gas sensors, for example. This is possible since the gases interact with the gate electrode material of the field-effect transistor. A selective adsorption of gases and/or a catalytic reaction take place at the gate electrode surface produced in accordance with the present invention. In this connection, highly sensitive and highly selective processes involving substances take place at the gate electrode surface. Gas adsorption and selective processes involving substances at the three-phase boundaries (metal phase, oxide ceramic phase and gas phase) lead to the formation of signal-generating polar or dipolar adsorbates. The characteristic and fine scale properties of the three-phase boundary are decisive for the sensitivity and response time of the gas sensor. The porosity of the gate electrode surface is able to be selectively adjusted by the method according to the present invention. In addition, the porous layers produced in accordance with the present invention are more resistant to thermal loading and, therefore, exhibit stable sensor signals over a broadened temperature range and over a longer operating time than the gate electrodes known from the related art.

Exemplary embodiments of the present invention are illustrated in the drawing and explained in greater detail in the following description.

### BRIEF DESCRIPTION OF THE DRAWINGS

FIG. 1 shows a TEM (transmission electron microscope) photograph of platinum colloids reduced in solution.

FIG. 2.1 shows a schematic representation of a suspension containing layer-forming particles that is applied to a substrate.

FIG. 2.2 shows the layer applied in FIG. 2.1 following preliminary drying.

FIG. 2.3 shows a schematic representation of a porous layer on a substrate.

FIG. 3.1 shows a schematic representation of a first porous layer on a substrate.

FIG. 3.2 shows a schematic representation of a two-layer structure.

FIG. 4 shows an REM (raster electron microscope) photograph of a porous layer of platinum produced in accordance with the present invention.

### DETAILED DESCRIPTION

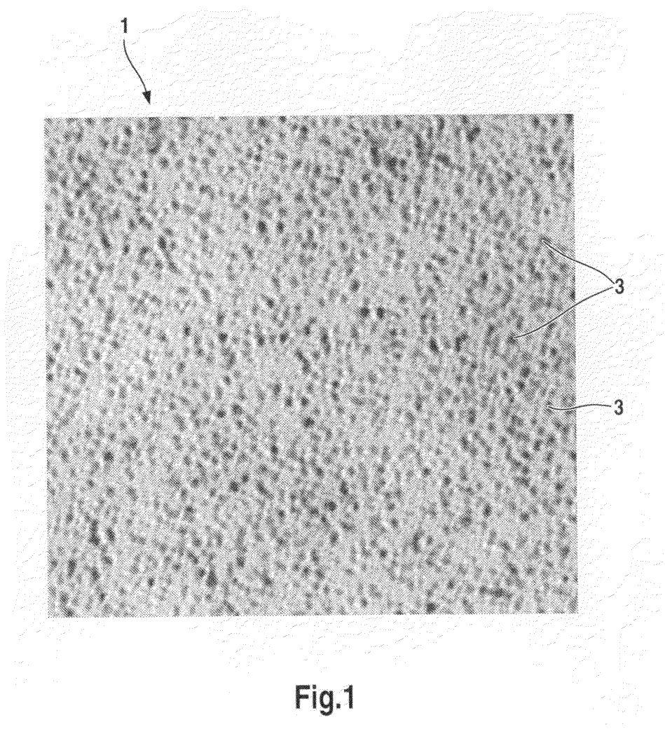

A transmission electron microscope photograph of a suspension containing platinum as layer-forming material is depicted in FIG. 1.

Particles 3 from a layer-forming material are contained in a suspension 1 which is used for producing a porous layer. As is discernible in FIG. 1, particles 3 from the layer-forming material are uniformly distributed in suspension 1. In the transmission electron microscope photograph depicted in FIG. 1, particles 3 are platinum colloids. To produce the platinum colloids, platinum in the form of one of its salts, for example as nitrate, chloride, bromide or carbonate, or in the form of one of its organometallic compounds, for example as acetate, alcoholate, acetylacetonate or as a corresponding organometal, is dissolved in a suitable solvent. Suited as solvents are, for example, alcohol, ether, glycol derivatives or N-containing solvents. The solution may also have a stabilizing agent added thereto. Diethylene glycol monobutylene ether may be used as a stabilizing agent, for example. The solution of the metal salt or of the organometallic compound is subsequently subjected to different reduction conditions. For the reduction, formaldehyde, formic acid, ethanol, hydrazine, hydrogen, borane derivatives or mixtures of ethanol with citric acid, ascorbic acid, hydrazine or glyoxylic acid are used, for example. The reducing agents are applied in each case in excess relative to the platinum.

Besides platinum colloids, as are illustrated in FIG. 1, metal colloids of the remaining elements of the 8th, 9th, 10th and 11th group of the periodic system are also suited for producing gate electrodes, which are used in semiconductor transistors. Particularly suited in addition to platinum are palladium, gold, silver, rhodium and iridium. In addition, as layer-forming material, ceramic particles may also be contained in the suspension.

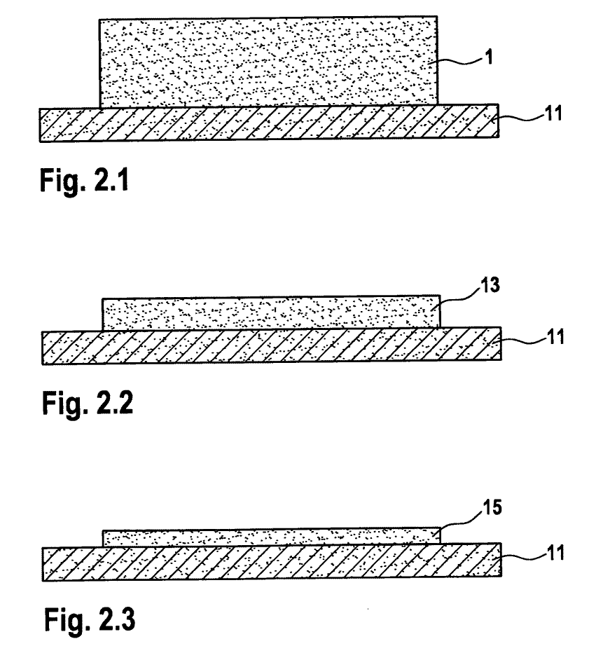

FIG. 2.1 schematically shows a substrate onto which a suspension containing particles from a layer-forming material was applied.

A substrate 11, onto which suspension 1 containing layer-forming particles 3 is applied, is, for example, a field-effect transistor, which is to be provided with a gate electrode. Suspension 1 is applied to substrate 11 with the aid of a dispenser, for example. A smooth, oxidic surface having minimal roughness is suited as a substrate, for example. A suitable suspension 1 contains, for example 3% by weight of polymethylene glycol, 1.75% by weight of platinum colloids having an average diameter d₅₀ of 50 nm, 0.25% by weight of Al₂O₃ having an average diameter d₅₀ of 200 nm, and 95% by weight of ethanol. Following the application, this suspension is predried at 30° C. Ethanol is removed from the suspension in the preliminary drying process. The volume of the layer applied to the substrate decreases. This is illustrated in FIG. 2.2. Once the ethanol has volatilized, the polyethylene glycol forms a solid matrix which contains platinum and aluminum oxide particles in a regular arrangement.

Following the drying process, the organic components are removed at a temperature of 400° C. over a time period of 4 h in the presence of air. When the organic matrix of polyethylene glycol is burned off, the layer-forming materials, namely the platinum and the aluminum oxide, leave behind a porous, uniform layer. This is illustrated in FIG. 2.3.

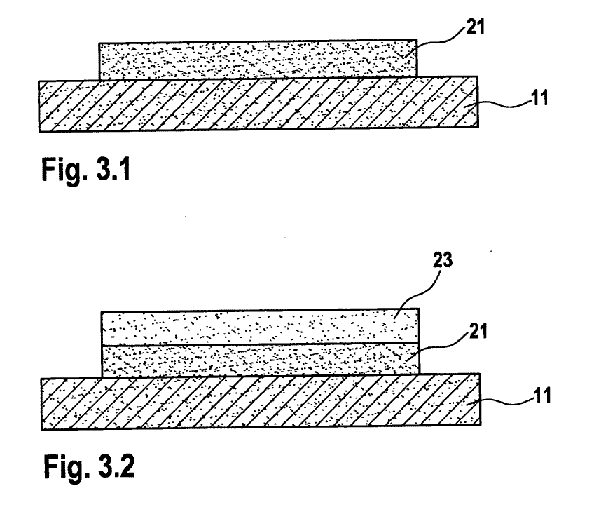

A multilayer structure of the porous coating on the substrate is schematically shown in FIGS. 3.1 and 3.2.

To produce a multilayer structure, a first porous layer 21 is first applied to substrate 11. To produce the two-layer structure, as shown in FIG. 3.2, first porous layer 21 is predried in a first specific embodiment, and a second porous layer 23 is subsequently applied, as shown in FIG. 3.2.

Following the application of second porous layer 23, it is likewise predried. The organic component is subsequently removed from first porous layer 21 and from second porous layer 23. It is also alternatively possible in another specific embodiment to first apply and to anneal first porous layer 21, and to apply second porous layer 23 to the hardened first porous layer 21.

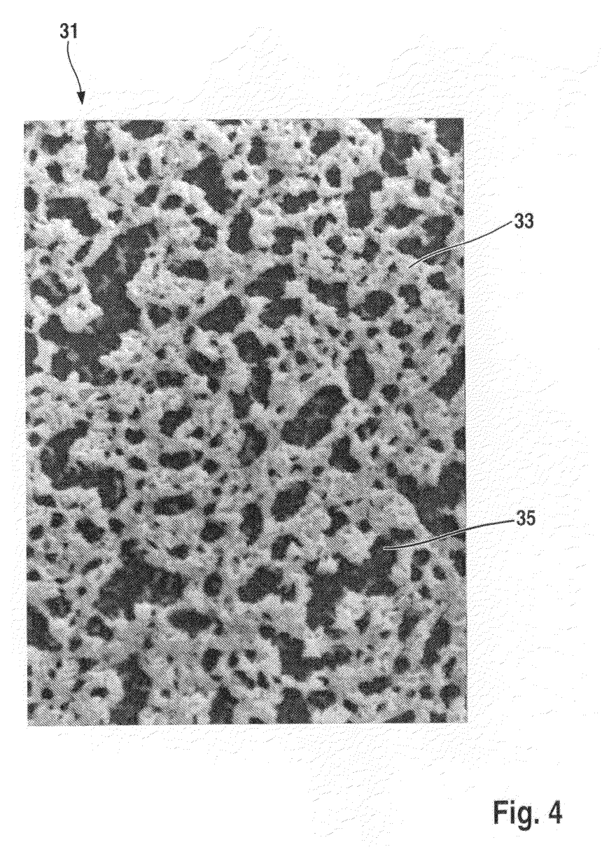

A raster electron microscope photograph of a porous layer produced in accordance with the present invention is shown in FIG. 4.

A porous layer 31, as shown in FIG. 4, was produced from suspension 1 illustrated in FIG. 1. The individual particles 3 from suspension 1 bond together to form a sponge-like structure 33. Voids 35 are formed in sponge-like structure 33. As is discernible in FIG. 4, voids 35 are uniformly distributed in porous layer 31. There is no discernible agglomeration of layer-forming material and, thus, no massive region in porous layer 31.

### EXAMPLES

### Example 1

A suspension of 3% by weight of polyethylene glycol, 1.75% by weight of platinum having an average particle diameter d₅₀, of 50 nm, 0.25% by weight of Al₂O₃ having an average diameter d₅₀ of 200 nm and 95% by weight of ethanol is applied by a dispenser to a smooth, oxidic surface having minimal roughness, so that 10 μl/cm⁻² remain. The suspension applied to the surface is predried at 30° C. and subsequently hardened at 150° C. for 2 h. Finally, the organic components are removed at 400° C. for 4 h in the presence of air.

Once the ethanol has volatilized, the polyethylene glycol forms a matrix which contains platinum and Al₂O₃ particles in a regular arrangement. When the organic matrix is burned off, the layer-forming materials leave behind a porous, uniform layer.

### Example 2

A suspension of 8% by weight of Pt(NO₃)₂, 2% by weight of ZrO₂ having an average diameter d₅₀ of 30 nm, 10% by weight of 1,2-propandiol, 80% by weight of ethanol and 2% by weight of latex spherules having an average diameter d₅₀ of 100 nm is applied using a dispenser to a smooth, oxidic surface having minimal roughness, so that 5 μl/cm⁻² remain. The suspension is initially predried for 2 h at 60° C. and then dried and hardened for 4 h at 120° C. in that the platinum is reduced. Following removal of the ethanol, the latex spherules form a regular arrangement of spherules in whose interstices are located the sintered platinum and zirconium dioxide and residues of the low-volatility solvent, 1,2-propandiol. In a next step, 10 μl/cm⁻² of a suspension of 5% by weight of Al(NO₃)₃, 2% by weight of urea, 81% by weight of water and 10% by weight of latex spherules having an average diameter of d₅₀ of 100 nm is applied. The substrate having the applied layers initially undergoes a thermal treatment for 8 h at 100° C. The organic, respectively volatile components are subsequently removed for 8 h at 300° C. under nitrogen and, subsequently thereto, for 4 hours at 480° C. under air. Following removal of the organic matrix, a mesoporous, uniform layer of a platinum-zirconium dioxide composite remains, which is covered with a mesoporous Al₂O₃ layer.

1-14. (canceled)

15. A method for producing at least one porous layer on a substrate, the method comprising:
(a) applying a suspension, which contains particles from a layer-forming material or molecular precursors of the layer-forming material, as well as at least one organic component, to the substrate;
(b) optionally reacting the precursors of the layer-forming material to produce the layer-forming material following application to the substrate;
(c) annealing the particles from the layer-forming material; and
(d) removing the at least one organic component.

16. The method of claim 15, wherein the layer-forming component contains at least one of at least one metal, at least one ceramic, and a mixture of at least one metal and at least one ceramic.

17. The method of claim 15, wherein the organic component which can cure to form a polymer matrix, includes at least one solvent, or a mixture thereof.

18. The method of claim 15, wherein the suspension also contains organic particles as a structure-directing component.

19. The method of claim 15, wherein the suspension contains at least one stabilizing agent.

20. The method of claim 17, wherein, following application of the suspension, solvent contained in the suspension is removed by drying.

21. The method of claim 17, wherein, once the suspension is applied and drying has been optionally carried out, monomers or oligomers contained in the suspension are optionally cured to form a polymer matrix.

22. The method of claim 15, wherein the layer-forming particles contained in the suspension have an average diameter of 0.5 to 1000 nm.

23. The method of claim 15, wherein the layer-forming particles are metal particles of at least one element of the 8th, 9th, 10th or 11th subgroup.

24. The method of claim 23, wherein the layer-forming particles are present as colloids, and wherein to produce the colloids, the at least one metal, in the form of its salt or in the form of an organometallic compound, is dissolved in a solvent and reduced under agitation.

25. The method of claim 24, wherein the solution also contains at least one stabilizing agent.

26. The method of claim 15, wherein the organic component is removed in operation (d) by thermolysis, pyrolysis, irradiation or chemical treatment.

27. The method of claim 15, wherein, to produce a thick porous layer, operations (a) through (c) are repeated before operation (d) is carried out, or operations (a) through (d) are repeated.

28. A field-effect transistor, comprising:
at least one gate electrode, the gate electrode having an electrically conductive, porous coating;
wherein the porous coating is applied by producing at least one porous layer on a substrate, by performing the following:
(a) applying a suspension, which contains particles from a layer-forming material or molecular precursors of the layer-forming material, as well as at least one organic component, to the substrate;
(b) optionally reacting the precursors of the layer-forming material to produce the layer-forming material following application to the substrate;
(c) annealing the particles from the layer-forming material; and
(d) removing the at least one organic component.

29. the method of claim 15, wherein the organic component includes one of monomers, oligomers or polymers.
